(19) United States
(12) Patent Application Publication
(10) Pub. No.: US 2024/0322520 A1
(43) Pub. Date: Sep. 26, 2024

(54) SEMICONDUCTOR LASER DEVICE

(71) Applicant: Ushio Denki Kabushiki Kaisha, Tokyo (JP)

(72) Inventors: Shigeta SAKAI, Tokyo (JP); Yutaka INOUE, Tokyo (JP); Masato HAGIMOTO, Tokyo (JP)

(73) Assignee: Ushio Denki Kabushiki Kaisha, Tokyo (JP)

(21) Appl. No.: 18/613,932

(22) Filed: Mar. 22, 2024

(30) Foreign Application Priority Data
Mar. 22, 2023 (JP) 2023-045926

(51) Int. Cl. H01S 5/042; H01S 5/40

(52) U.S. Cl. CPC H01S 5/0428; H01S 5/4031

(57) ABSTRACT

A semiconductor laser apparatus includes a drive circuit and an edge emitting semiconductor laser device. An envelope of a spectrum of light emitted from one light emitter when laser oscillation is performed by pulse driving is formed by synthesizing spectra of a plurality of peaks, and a full width at half maximum of the envelope is 3 nm or more.

### BACKGROUND

### 1. Technical Field

The present disclosure relates to a semiconductor laser apparatus.

### 2. Description of the Related Art

In recent years, various reality technologies such as augmented reality (AR), virtual reality (VR), mixed reality (MR), and substitutional reality (SR) have been put into practical use in various fields, and display devices such as a head mount display (HMD), a head-up display (Head-up Display), and AR glasses using these technologies have been commercialized.

In particular, a system using laser of three primary colors of RGB as a light source and micro electro mechanical systems (MEMS) as a spatial modulation element for image display has advantages such as wide color gamut, high resolution, and wide viewing angle. In addition, by forming the light source into multi-beams of respective colors (forming a plurality of light sources), higher resolution and a wide viewing angle become possible. Further, more realistic AR/MR can be realized with a hologram technology using a diffraction pattern.

In a display system using an RGB laser and a MEMS, when an image is formed through a waveguide, there is a problem that fringes (Newton's ring) of a light and dark interference pattern is formed because of interference of laser light in the waveguide, the fringes are reflected in the image, and image quality deteriorates. The appearance of fringes due to such an interference pattern is caused by high coherence of laser light. This interference pattern can be solved by increasing the full width at half maximum of the spectrum and decreasing the monochromaticity.

As a countermeasure against such a problem of interference pattern, a method of operating a semiconductor laser of a light source with an extremely short pulse width and widening an oscillation spectrum width by using high-frequency superposition may be used. However, in a red semiconductor laser, even when high-frequency superposition is used, the wavelength width can be expanded only up to 2 nm, and a sufficient countermeasure for the interference pattern cannot be taken.

### SUMMARY

One aspect of the present disclosure has been made in such a circumstance, and one exemplary object thereof is to provide a semiconductor laser apparatus having a wide spectral width.

A semiconductor laser device according to one aspect of the present disclosure is an edge-emitting type semiconductor laser, wherein an envelope of a spectrum of light emitted from one light emitter when laser oscillation is performed by pulse driving is formed by synthesizing spectra of a plurality of peaks, and a full width at half maximum of the envelope is 3 nm or more. The envelope of the spectrum may have a plurality of local maximum values (local maximum points). Although details will be described later, the full width at half maximum of the envelope of the spectrum described above is preferably 10 nm or less for the reason that color reproducibility in a wearable display device deteriorates when the full width at half maximum exceeds 10 nm. Further, in the present specification, the full width at half maximum is defined as a difference between the longest wavelength and the shortest wavelength in the intensity corresponding to half the maximum value of the peak wavelength indicated by the envelope. Synthesis of spectra of a plurality of peaks means that the envelope is represented by a sum of a plurality of (a few) peak functions. In one embodiment, a parameter of each Gaussian distribution may be assigned and calculated such that the spectrum of the sum of the plurality of Gaussian distributions fits the spectrum represented by the envelope. This makes it possible to separate the spectrum of the envelope into spectra of a plurality of peaks. Each peak thus separated is a local maximum point. In one embodiment, fitting may be performed by a least squares method such that the sum of the two Gaussian functions matches a smoothed spectrum. Even though the envelope looks like a single Gaussian distribution, whether or not the envelope is an envelope formed by combining a plurality of Gaussian distributions may be found out depending on whether or not the oscillation peaks are separated by increasing the pulse width of the driving pulse to light up.

A semiconductor laser apparatus according to one aspect of the present disclosure includes a semiconductor laser device of an edge-emitting type and a drive circuit that pulse-drives the semiconductor laser device. When the semiconductor laser device is driven by a drive current having a short pulse width, a phenomenon occurs in which a spectrum is widened as compared with the case of CW (Continuous Wave) driving. A wide band spectrum can be obtained by causing this phenomenon to occur in two or more spectra close to each other and causing the plurality of spread spectra to continue.

A semiconductor laser apparatus according to one aspect of the present disclosure includes a semiconductor laser device of an edge-emitting type including a light-emitting layer configured such that a plurality of peaks exist in a gain spectrum, and a drive circuit that pulse-drives the semiconductor laser device.

Another aspect of the present disclosure is also a semiconductor laser apparatus. The semiconductor laser apparatus includes a semiconductor laser device of an edge-emitting type having non-linearity in I-L characteristics, and a drive circuit that pulse-drives the semiconductor laser device.

Still another aspect of the present disclosure is also a semiconductor laser apparatus. The semiconductor laser apparatus includes a semiconductor laser device of an edge-emitting type that oscillates with two wavelengths when CW driving is performed, and a drive circuit that pulse-drives the semiconductor laser device.

Any combinations of the above-described components and mutual replacement of components and expressions among methods, devices, systems, and the like are also effective as aspects of the present disclosure. Further, the description of this item (means for solving the problem) does not describe all the essential features of the present disclosure, and thus subcombinations of these features described may also be the present disclosure.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram of a semiconductor laser apparatus according to an embodiment;

FIG. 2 is a diagram for describing the operation of the semiconductor laser apparatus of FIG. 1;

FIG. 3 is a diagram illustrating a variation of an emission spectrum (envelope) of the semiconductor laser apparatus;

FIG. 4 is a diagram illustrating I-L characteristics when a sample having a ridge width of 3 μm is subjected to CW driving;

FIG. 5 is a diagram illustrating I-L characteristics of a sample having a ridge width of 3 μm and dP/dI obtained by differentiating the I-L characteristics;

FIG. 6 is a diagram illustrating a spectrum when a sample having a ridge width of 3 μm is subjected to CW driving with different current amounts;

FIG. 7 is a plan view and a sectional view of a semiconductor laser device according to Example 3;

FIG. 8 is a diagram illustrating a waveform of a drive current used in an experiment;

FIG. 9 is a diagram illustrating an oscillation spectrum of a semiconductor laser apparatus;

FIG. 10 is a diagram illustrating the dependence of the oscillation spectrum on the drive waveform;

FIG. 11 is a diagram illustrating the dependence of the spectrum and the optical waveform on a pulse width τ of a drive current I_{DRV}; and

FIG. 12 is a diagram illustrating a pulse width of an optical waveform and a full width at half maximum of an envelope spectrum.

### DETAILED DESCRIPTION

### Outline of Embodiment

An outline of some exemplary embodiments of the present disclosure will be described. This outline is intended as an introduction of the detailed description that follows, or for a basic understanding of the embodiments. This summary describes some concepts of one or more embodiments in a simplified manner, and does not limit the scope of the invention or disclosure. Also, this summary is not a comprehensive overview of all possible embodiments and does not limit the essential components of the embodiments. For convenience, “one embodiment” may be used to refer to one embodiment (example or modification) or a plurality of embodiments (example or modification) disclosed in the present specification.

A semiconductor laser device according to one embodiment is an edge-emitting type semiconductor laser, wherein an envelope of a spectrum of light emitted from one light emitter when laser oscillation is performed by pulse driving is formed by synthesizing spectra of a plurality of peaks, and a full width at half maximum of the envelope is 3 nm or more.

On one embodiment, the envelope of the spectrum may have a plurality of local maximum points. A difference between a first wavelength corresponding to a first local maximum value which is a largest local maximum value and a second wavelength corresponding to a second local maximum value which is a next largest local maximum value may be 1 nm or more and 10 nm or less.

In one embodiment, a local minimum value sandwiched between the first local maximum value and the second local maximum value may be a half value or more of the first local maximum point.

In one embodiment, the oscillation wavelength of the semiconductor laser device may be in a visible light region.

In one embodiment, the oscillation wavelength of the semiconductor laser device may be in a red wavelength region.

In one embodiment, the semiconductor laser device may include a plurality of emitters.

In one embodiment, an I-L characteristic during CW driving may have a kink region.

In one embodiment, an emission wavelength difference of 1 nm to 10 nm may exist in a gain region in a chip plane of the semiconductor laser device with respect to a waveguide direction.

In one embodiment, the semiconductor laser device may include a light-emitting layer having a stacked structure of two or more well layers having emission wavelengths different from each other by 1 nm to 10 nm.

In one embodiment, the semiconductor laser device may include a light-emitting layer structured such that a plurality of peaks exist in a gain spectrum.

A semiconductor laser apparatus according to one embodiment may include any of the semiconductor laser devices described above and a drive circuit that pulse-drives the semiconductor laser device.

In one embodiment, the drive circuit may drive the semiconductor laser device with a pulse current at which a pulse width of an optical waveform of emission light is 4 ns or less.

A semiconductor laser apparatus according to one embodiment may include any of the semiconductor laser devices described above and a drive circuit that pulse-drives the semiconductor laser device. The peak of the pulsed drive current supplied to the semiconductor laser device may be located in the kink region.

A semiconductor laser apparatus according to one embodiment includes a semiconductor laser device of an edge-emitting type including a light-emitting layer configured such that a plurality of peaks exist in a gain spectrum, and a drive circuit that pulse-drives the semiconductor laser device.

By pulse-driving the semiconductor laser device, each peak of the gain spectrum is widened, and the widened adjacent peaks are continued, whereby a broadband spectrum can be obtained.

A semiconductor laser apparatus according to one embodiment includes an edge emitting semiconductor laser device having non-linearity in I-L characteristics, and a drive circuit that pulse-drives the semiconductor laser device.

In the semiconductor laser device in which the I-L characteristic has non-linearity, the oscillation wavelength is shifted or multi-wavelength oscillation occurs depending on the amount of the drive current during the CW drive. By pulse-driving such a semiconductor laser device, a broadband spectrum can be obtained.

A semiconductor laser apparatus according to one embodiment includes an edge emitting semiconductor laser device that oscillates with two wavelengths when CW driving is performed, and a drive circuit that pulse-drives the semiconductor laser device.

By pulse-driving the semiconductor laser device, spectra of two wavelengths are widened, and they are continued, whereby a broadband spectrum can be obtained.

In one embodiment, the emission wavelength of the semiconductor laser device may be in a visible light region.

In one embodiment, the emission wavelength of the semiconductor laser device may be in a red wavelength region.

In one embodiment, the spectrum of light emitted from the semiconductor laser device has a plurality of local maximum points (values), and the difference between a first wavelength corresponding to a largest first local maximum value and a second wavelength corresponding to a second local maximum value that is the second largest value may be 1 nm or more and 10 nm or less.

In one embodiment, in the envelope of the spectrum, a minimum local value sandwiched between the first local maximum value and the second local maximum value may be equal to or more than a half value of the first local maximum value.

In one embodiment, the spectrum of light emitted from the semiconductor laser device may have a full width at half maximum of 3 nm or more. When the full width at half maximum is larger than 3 nm, the effect of image quality improvement can be obtained in the case of use in a wearable display device using a waveguide.

In one embodiment, in the semiconductor element, an emission wavelength difference of 1 nm to 10 nm may exist in a gain region in a chip plane of the semiconductor laser device with respect to a waveguide direction.

In one embodiment, the light-emitting layer may have a stacked structure of two or more well layers having emission wavelengths different from each other by 1 nm to 10 nm.

In one embodiment, the semiconductor laser device may include a plurality of emitters. In this case, at least one emitter may have any of the features described above.

In one embodiment, the drive circuit may drive the semiconductor laser device with a pulse current at which a pulse width of an optical waveform of emission light is 4 ns or less.

In one embodiment, in the semiconductor element, an I-L characteristic during CW driving may have a kink region.

In one embodiment, the peak of the pulsed drive current supplied by the drive circuit to the semiconductor laser device may be located in the kink region.

A wearable display device according to one embodiment includes any of the semiconductor laser apparatuses described above.

### EMBODIMENT

Hereinafter, the present disclosure will be described with reference to the drawings on the basis of preferred embodiments. The same or equivalent components, members, and treatments illustrated in the respective drawings are denoted by the same reference numerals, and redundant description will be omitted as appropriate. The embodiments are not intended to limit the disclosure, but are merely examples, and all features described in the embodiments and combinations thereof are not necessarily essential to the disclosure.

Dimensions (thickness, length, width, and the like) of each member described in the drawings may be appropriately enlarged or reduced for easy understanding. Further, the dimensions of a plurality of members do not necessarily indicate the magnitude relationship therebetween, and even though a certain member A is drawn thicker than another member B in the drawing, the member A may be thinner than the member B.

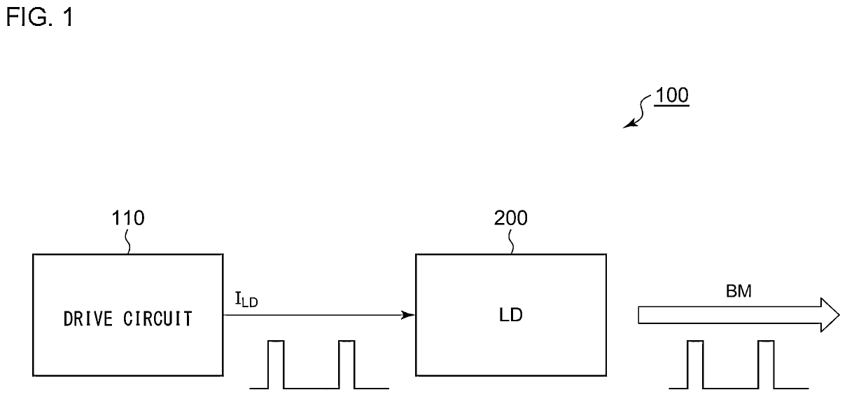

FIG. 1 is a block diagram of a semiconductor laser apparatus according to an embodiment. The semiconductor laser apparatus 100 includes a drive circuit 110 and a semiconductor laser device 200. The semiconductor laser device 200 is an edge emitting semiconductor laser.

The drive circuit 110 supplies a pulsed drive current I_{DRV} to the semiconductor laser device 200 (pulse driving). The semiconductor laser device 200 emits laser beam BM having a wider spectrum than that in CW driving by performing pulse driving under an appropriate condition. In the present embodiment, the semiconductor laser device 200 is structured such that this phenomenon occurs in a plurality of adjacent wavelength bands. Specifically, the semiconductor laser device 200 is structured such that the envelope of the spectrum of the laser beam BM is formed by synthesizing spectra of a plurality of peaks when laser oscillation is performed by pulse driving. The full width at half maximum of the envelope of the spectrum of the laser beam BM is 3 nm or more.

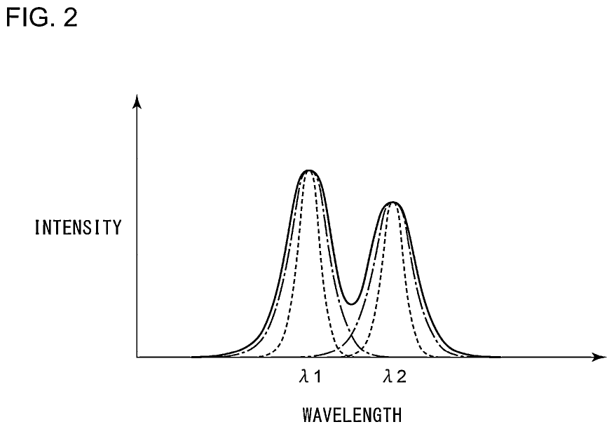

FIG. 2 is a diagram for describing the operation of the semiconductor laser apparatus 100 of FIG. 1. The broken line indicates a spectrum during the CW driving, and the alternate long and short dash line indicates a spectrum during the pulse driving. Since the semiconductor laser device 200 oscillates in a longitudinal multimode, the actual spectrum is a set of line spectra corresponding to a plurality of longitudinal modes, but only the envelope is illustrated here.

In the example of FIG. 2, in two wavelengths (wavelength bands) having wavelengths λ1 and λ2 as peaks, widening of the spectrum line due to pulse driving has occurred, and the two widened spectra are connected to form one continuous spectrum having a wide band indicated by the solid line.

According to the semiconductor laser apparatus 100, it is possible to generate light having a spectral width (envelope full width at half maximum) exceeding a full width at half maximum of 2 nm, or further exceeding 3 nm, which has been conventionally difficult. When the full width at half maximum is larger than 3 nm, the effect of image quality improvement can be obtained in the case of use in a wearable display device using a waveguide.

The emission wavelengths λ1 and λ2 of the semiconductor laser device 200 may be in a red wavelength region.

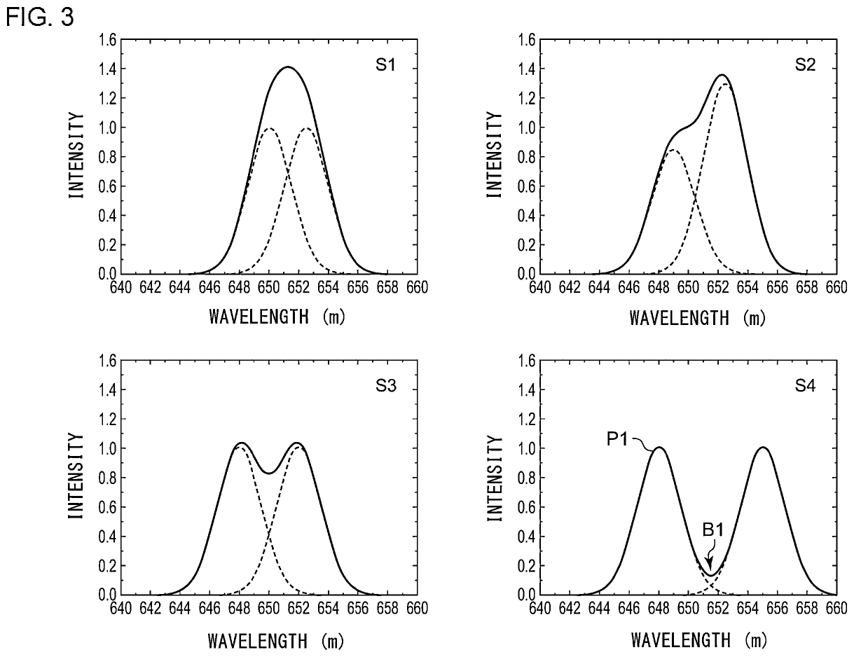

FIG. 3 is a diagram illustrating a variation of an emission spectrum (envelope) of the semiconductor laser apparatus 100. Here, the semiconductor laser device 200 is a red laser, and a spectrum component in which two wavelength widths of λ1=650 nm and λ2=653 nm are enlarged is synthesized. In S1, the peaks of the two different-wavelength components λ1 and λ2 having an enlarged spectrum width overlap each other to form a unimodal spectrum. In S2, the peaks of the two different-wavelength components λ1 and λ2 having an enlarged spectrum width overlap each other to form a unimodal spectrum, but since the peak intensities of the different-wavelength components λ1 and λ2 are different, an asymmetric unimodal spectrum is formed.

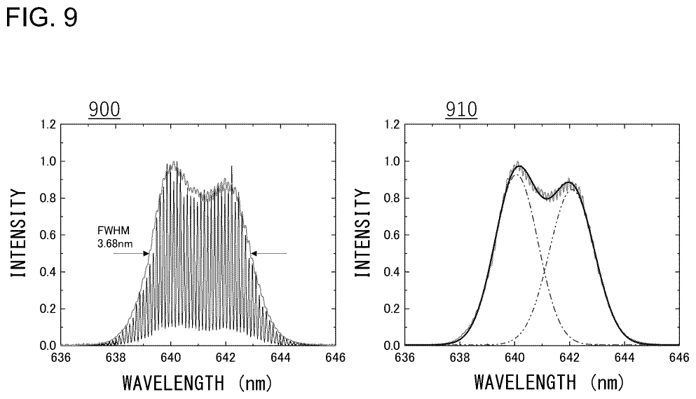

S3 and S4 indicate a state in which two different-wavelength peaks with enlarged spectral widths overlap each other to form a bimodal spectrum. When the different wavelengths λ1 and λ2 are close as in S3, the valley between the peaks becomes shallow, and when the different wavelengths λ1 and λ2 are far as in S4, the valley between the peaks becomes deep. As will be described later with reference to FIG. 9, when the intensity of the different wavelength λ2 is higher than half the intensity of the different wavelength λ1 as in S4, the full width at half maximum is from the left side of the different wavelength λ1 to the right side of the different wavelength λ2 regardless of the depth of the valley between the peaks. In S4, the full width at half maximum is 10 nm from about 646 nm to about 656 nm.

As illustrated in FIGS. 2 and 3, the spectrum of the light emitted from the semiconductor laser device 200 has a plurality of local maximum points (values). Here, two local maximum points are illustrated, but in principle, three or more local maximum points can be provided. When the difference Δλ between the first wavelength corresponding to the largest first local maximum value and the second wavelength corresponding to the second local maximum value, which is the second largest value, is too small, the effect of spectrum width expansion by synthesis is weakened. On the other hand, when the wavelength difference Δλ exceeds 10 nm, the optical full width at half maximum becomes substantially the same as that of the LED (light emitting diode), and conversely, the coherence becomes insufficient and the color reproducibility decreases. In consideration of these, the wavelength difference Δλ may be 1 nm or more and 10 nm or less.

It is not preferable that the valley of the two peaks is too deep as in S4 in FIG. 3, in other words, that the ratio B1/P1 between the largest first local maximum value P1 and the local minimum value B1 is too small. The allowable range depends on the application in which the semiconductor laser apparatus 100 is used, but for example, the local minimum value is preferably ½ or more of the first local maximum value.

The emission wavelength of the semiconductor laser device 200 is not limited to red, and may be any color in the visible light region. The semiconductor laser device 200 of light in a visible light region, particularly, three primary colors of R, G, and B is used in a wearable display device. In such an application, when laser light having a narrow spectrum width, that is, having high coherence is used, there is a problem that fringes of a light and dark interference pattern are reflected in an image due to interference of the laser light in the waveguide, and image quality deteriorates. The technique for expanding the spectral width according to the present disclosure is suitable for such applications.

The present disclosure extends to various devices and methods understood as the block diagram of FIG. 1 or derived from the above description, and is not limited to a specific configuration. Hereinafter, more specific configuration examples and examples will be described to help understanding of the present disclosure and the essence and operation of the present disclosure and to clarify them but not to narrow the scope of the present disclosure.

### Example 1

In Example 1, a semiconductor laser device 200 having a kink and a remarkable wavelength hopping associated with the kink in I-L characteristics was produced. The multilayer structure was prepared by coherently growing an n-type cladding layer, a lower guide layer, an active layer, an upper guide layer, a p-type cladding layer, an interface layer, and a contact layer in this order on a GaAs substrate by a metal organic chemical vapor deposition (MOCVD) method. In this example, the n-type cladding layer was made of Si-doped AlInP having a thickness of 2 μm. The lower guide layer was x=0.7 and y=0.5 in (AlₓGa₁₋ₓ)_{1-y}In_{y}P having a thickness of 60 nm. The active layer was a lattice-matched GaInP having two well layers, and the well thickness was 5 nm. Similarly to the lower guide layer, the upper guide layer was (AlₓGa₁₋ₓ)_{1-y}In_{y}P (x=0.7, y=0.5) having a thickness of 60 nm. The p-type cladding layer was Mg-doped AlInP having a thickness of 1 μm. As the cladding layer and the contact layer, an interface layer in which a band gap was changed stepwise was prepared. AlInP, a GaInP layer, and an AlGaAs layer were sequentially formed on the interface layer, AlInP and GaInP were doped with Mg, and AlGaAs was doped with Zn. A GaAs layer doped with Zn was formed on the contact layer. After the multilayer growth step described above, ridge stripe formation and electrode formation are performed in the same manner as in the conventional method, and the semiconductor laser device 200 is produced by cleavage/end surface coating and chipping.

Here, the ridge width affects the degree of kink. To verify the influence of the degree of kink on the expansion of the spectrum width, five specifications having ridge widths of 1.5 μm, 2.0 μm, 3.0 μm, 3.5 μm, and 4.0 μm were separately prepared in the same wafer. The design cutoff width is 1.5 μm. The semiconductor laser device 200 having an element length of 400 μm, a reflectance on the rear side of 90%, and a reflectance on the front (emission side) side of 10% was produced from the wafer produced with such specifications.

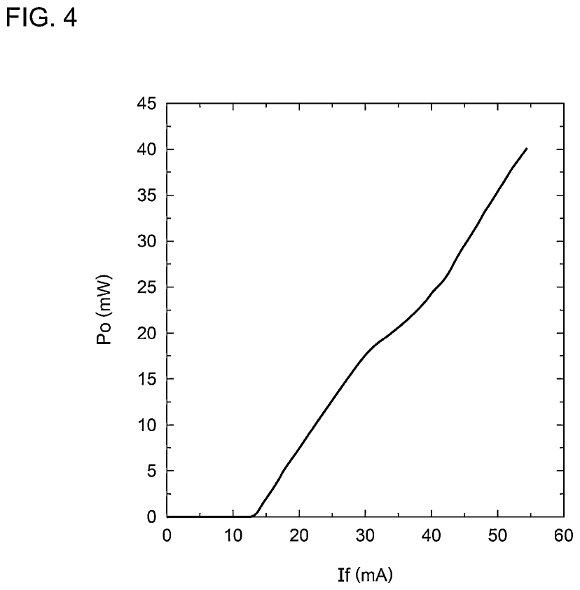

FIG. 4 is a diagram illustrating I-L characteristics when the sample having a ridge width of 3 μm was subjected to CW driving. In this sample, kink was observed at around 35 mA. The I-L characteristics of the other samples were evaluated in the same manner, and kink was confirmed in samples having a ridge width of 2 μm or more.

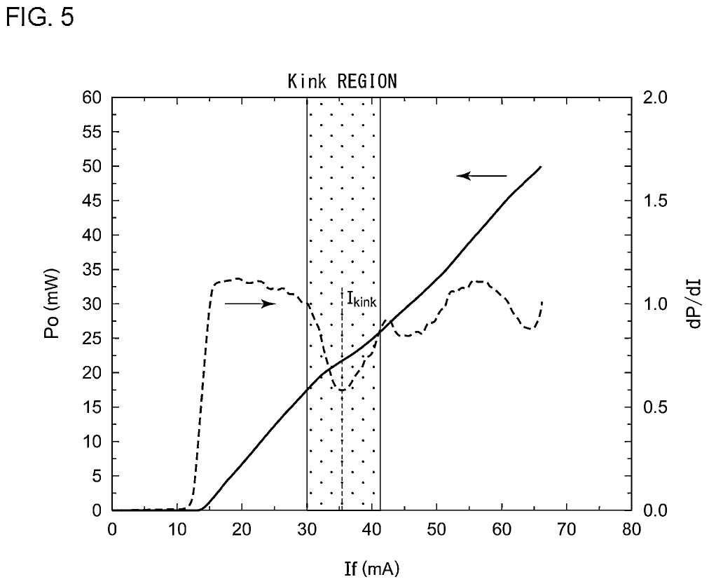

FIG. 5 is a diagram illustrating I-L characteristics of the sample having a ridge width of 3 μm and dP/dI obtained by differentiating the I-L characteristics. In an ideal device without kink, dP/dI shows a constant value, but in a device with kink, dP/dI shows a characteristic of decreasing and increasing with an increase in I. A region where dP/dI decreases then increases again is referred to as a kink region, and a current If when dP/dI becomes minimum in the kink region is referred to as a kink level. In the I-L characteristics, when there are a plurality of kink levels, a point at which the current is the smallest is set as the kink level. The influence of kink does not appear singularly at one point of the kink level, but has an influence within a specific section around the kink level. In the present specification, in view of such a physical phenomenon, a current range of +20% of the kink level is defined as the kink region.

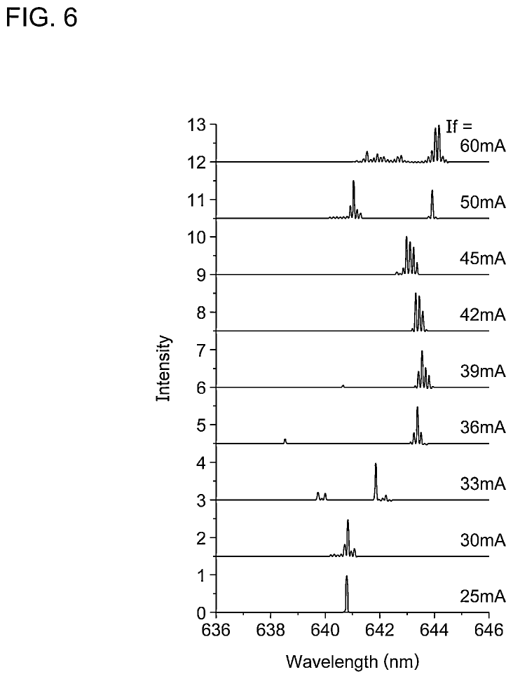

FIG. 6 is a diagram illustrating a spectrum when the sample having a ridge width of 3 μm was subjected to CW driving with different current amounts. In a region where the current was smaller than that in the kink region where kink appears, oscillation occurred at a peak, whereas in the kink region, wavelength hopping was observed. In addition, in a region where the current amount was larger (50 mA, 60 mA) than that in the kink region, oscillation at two wavelengths was observed.

When a sample exhibiting such characteristics is driven by a drive current having an appropriate waveform, a plurality of wavelength components spreads, and the wavelength components are synthesized to obtain a broad spectrum.

### Example 2

In Example 2, an active layer formed by stacking two well layers having different band gaps was formed, and a semiconductor laser device having two peaks in a gain spectrum was produced. Since the structure other than the active layer structure and the production process are basically the same as those in Example 1, only the modifications from Example 1 will be described.

The active layer is formed of two well layers and a barrier layer sandwiched therebetween. The well layers are each 5 nm thick GaInP but differ slightly in In composition. In the present embodiment, a trimethylindium (TMI) flow rate during GaInP growth was adjusted such that a photoluminescence (PL) wavelength of a well layer was changed by 5 nm.

Regarding the arrangement of the well layers, from the viewpoint of uniform injection of carriers (in particular, holes), it is desirable to dispose the well layers such that the band gap becomes smaller toward the n side. Regarding the number of well layers, the effect of the present disclosure can be obtained by providing an appropriate band gap difference even when the number is three or more, but two layers are desirable from the viewpoint of uniform injection of carriers. In the present embodiment, a band gap difference was provided by making a difference in In composition for each well layer, but a difference may be provided in a well width instead of the composition, and a light emission level difference may be provided using a difference in quantum confinement energy. The barrier layer had a thickness of 30 nm and was made of (AlₓGa₁₋ₓ)_{1-y}In_{y}P (x=0.7, y=0.5) like the guide layer. Setting the barrier layer thickness to a thickness of 10 nm or more makes it possible to suppress tunneling of injected carriers and promote uniformization of the gain between the wells. Whether the gain spectrum can be appropriately controlled by the plurality of different quantum well structures can be evaluated using, for example, the Hakki-Paoli method.

The semiconductor laser device 200 was produced by the same process as in Example 1 by using a wafer having such an active layer structure. However, in this example, to realize the two-wavelength oscillation according to the structure of the active layer instead of the kink of the I-L characteristics, the element was produced with a ridge width of 1.5 μm, which was smaller than the cutoff width.

### Example 3

In Example 3, the band gap of the active layer was spatially changed with respect to the stripe direction (waveguide direction of laser light) using a selective growth technique. When the device produced by such a method was driven by using high-frequency superimposition, both the linearity of the I-L characteristics and the increase in the spectral full width at half maximum of the emitted light was able to be achieved.

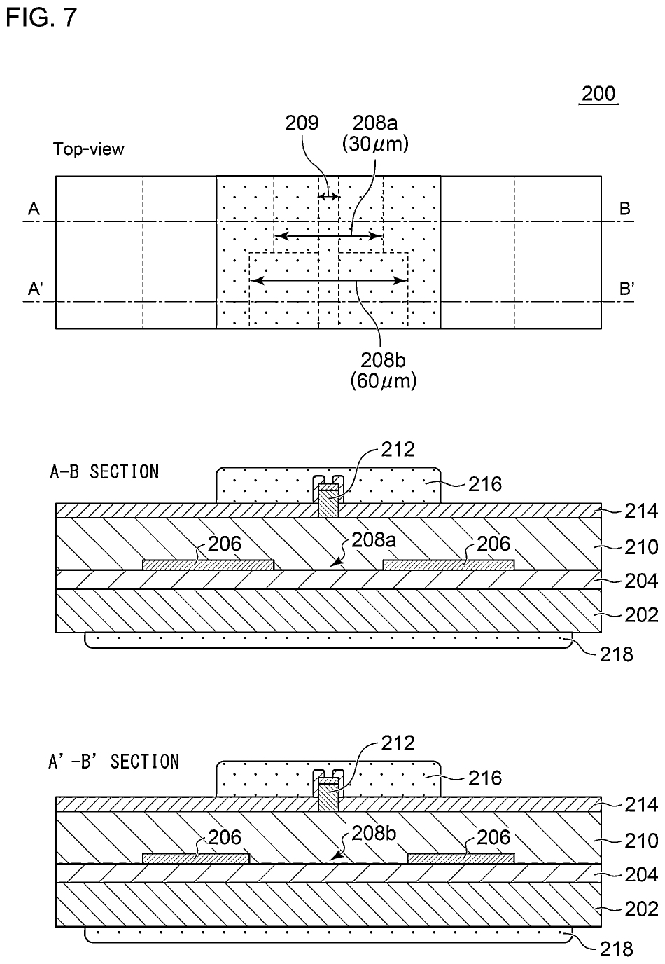

FIG. 7 is a plan view and a sectional view of the semiconductor laser device 200 according to Example 3.

First, Si-doped AlInP with a thickness of 2 μm is epitaxially grown on an n-type GaAs substrate 202 as an n-type cladding layer 204 by the MOCVD method, and then the wafer is taken out from the MOCVD furnace once to form a selective growth mask. In the present embodiment, a SiO₂ film 206 was formed on the wafer surface by the CVD method, and an opening 208 having a different opening width depending on the position in the resonator direction was formed by photolithography and wet etching. The material of the selective mask is not limited to SiO₂, and for example, SiN may be used, and sputtering or an atomic layer deposition (ALD) method may also be used as a film formation method. In the pattern of the selective mask, the opening diameters of the wide portion and the narrow portion of the opening 208 were 60 μm and 30 μm, respectively.

In selective growth, since the growth rate and composition of the selective growth portion can be changed depending on the opening diameter of the selective mask, the band gap of the active layer can be changed in the stripe plane by using patterning in which the opening width is changed stepwise. Here, since the effect in the present embodiment can be obtained as long as the band gap of the active layer can be spatially changed in the stripe direction, the patterning shape in selective growth is not limited to the above example. For example, the opening width can be continuously changed. After the selection mask is formed, a multilayer growth layer 210 including a lower guide layer, an active layer, an upper guide layer, a p-type cladding layer, an interface layer, and a contact layer is sequentially formed by regrowth by MOCVD. Here, to produce a waveguide, the guide layer needs to be adjusted in composition so as to have a refractive index higher than that of the cladding layer. In this example, in (AlₓGa₁₋ₓ)_{1-y}In_{y}P, X=0.7 and y=0.5 were satisfied, and the thickness was 100 nm. In the active layer, the well layer was formed of two layers of Ga_{0.5}In_{0.5}P having a thickness of about 5 nm, and the barrier layer between the well layers was formed of Al_{0.35}Ga_{0.15}In_{0.5}P similar to the guide layer. As the cladding layer and the contact layer, an interface layer in which a band gap was changed stepwise was prepared. AlGaInP and GaInP layers were sequentially formed on the interface layer, and AlGaInP and GaInP were doped with Mg. A GaAs layer doped with Zn was formed on the contact layer.

After the formation of the multilayer growth layer 210, ridge stripes 209 were formed in the same manner as in the conventional method, electrodes 216 and 218 were formed, and the semiconductor laser device 200 was produced by cleavage/end surface coating and chipping. In this example, a ridge structure was formed by dry etching so that the ridge width was 2 μm. The cleavage was set to 600 μm, and in the end surface coating, the reflectance on the rear side was set to 90%, and the reflectance on the front (emission) side was set to 10%.

### Verification Experiment

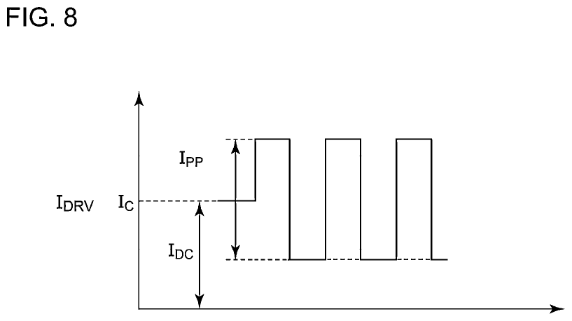

As an experiment for verifying spectrum width expansion in the semiconductor laser apparatus 100 according to the present embodiment, an evaluation result example of an element produced according to Example 2 will be described. A drive current waveform used for driving the semiconductor laser device 200 will be described with reference to FIG. 8. FIG. 8 is a diagram illustrating a waveform of a drive current used in the experiment. The drive current I_{DRV} has a waveform in which the high-frequency current AC having an amplitude Ipp is superimposed on the DC component of the current amount Ic.

First, the semiconductor laser device 200 was driven at a high frequency by the pulsed drive current I_{DRV} having a pulse width τ=1 ns and a duty cycle of 50%, and an oscillation spectrum was evaluated with a spectrum analyzer. The amplitude current of the drive current was set to Ipp=40 mA, and the amplitude center current I_{c} was set to 17 mA.

FIG. 9 is a diagram illustrating an oscillation spectrum of the semiconductor laser apparatus 100. In 900 of FIG. 9, an envelope of the oscillation spectrum was also plotted in a superimposed manner by smoothing processing. In addition, 910 of FIG. 9 illustrates two Gaussian distributions fitting the envelope spectrum and a spectrum obtained by synthesizing the two Gaussian distributions. It can be seen that the envelope spectrum and the synthesized spectrum are in good agreement. The envelope spectrum had a broad shape with two peaks. The wavelength difference between the peaks is about 1.87 nm, the full width at half maximum of the envelope spectrum is 3.68 nm, and it can be seen that the effect of sufficient spectrum expansion is obtained.

Here, to calculate the full width at half maximum from the envelope, the measurement data is smoothed, normalized by the maximum value of the data, and the difference between the longer wavelength side and the shorter wavelength side of the spectrum is obtained. Vibration in a small period is observed in the oscillation spectrum and the envelope spectrum obtained by the smoothing processing, but this is derived from interference in the resonator. In this example, a spectrum at the time of high-frequency superimposition was measured using a spectrum analyzer having a wavelength resolution of about 0.02 nm, and smoothing data was calculated by moving average processing in a section of a 0.6 nm region to obtain data of the envelope.

Here, the envelope is obtained by smoothing the measurement data and normalizing the smoothed measurement data with the maximum value of the measurement data. Vibration in a small period is observed in the oscillation spectrum and the envelope spectrum obtained by the smoothing processing, but this is derived from interference in the resonator. Thus, when the peak of the envelope spectrum is calculated, the local maximum point in the spectrum ignoring the vibration is used. Specifically, as illustrated in FIG. 9, the local maximum point can be used in a spectrum obtained by synthesizing a plurality of Gaussian distributions fitted to the envelope spectrum. In this example, a spectrum at the time of high-frequency superimposition was measured using a spectrum analyzer having a wavelength resolution of about 0.02 nm, and smoothing data was calculated by moving average processing in a section of a 0.6 nm region. The wavelength difference between the peaks can be calculated by ignoring the vibration due to the interference and using the local maximum wavelength difference from this spectrum.

Next, a result of performing the same evaluation on the same sample under different conditions of high frequency driving will be described.

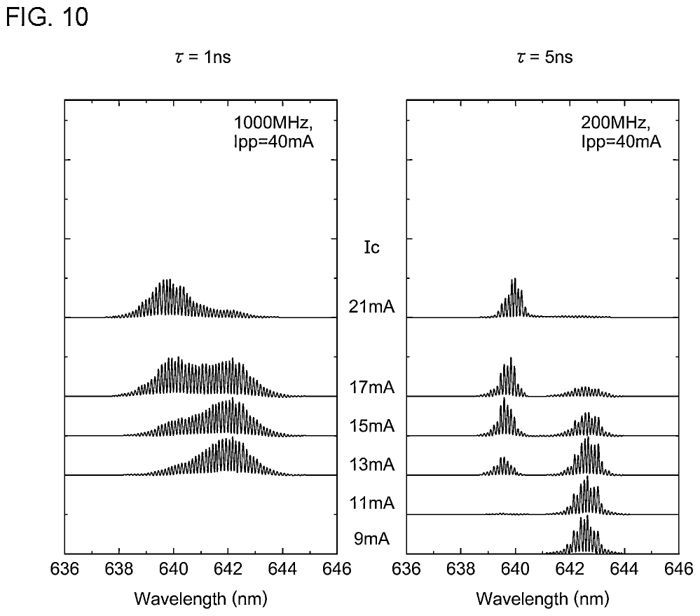

FIG. 10 is a diagram illustrating the dependence of the oscillation spectrum on the drive waveform. The pulse amplitude current Ipp was fixed at 40 mA, and the spectrum was measured while changing the amplitude center current I_{c} to 9 mA, 11 mA, 13 mA, 15 mA, 17 mA, and 21 mA. The left part of FIG. 10 illustrates a spectrum when the pulse width τ was 1 ns (pulse frequency 500 MHZ), and the right part of FIG. 10 illustrates a spectrum when the pulse width τ was 5 ns (pulse frequency 100 MHZ).

Under the operating condition of τ=1 ns, as illustrated in the left part of FIG. 10, the intensity ratio of the two peaks of the spectrum changed with the change in the amplitude center current I_{c}. In the intensity ratio of the spectrum, the peak on the long wavelength side was large when the amplitude center current was sufficiently small, and the peak on the short wavelength side was large when the amplitude center current was sufficiently large.

Further, when a similar spectrum was acquired by changing the pulse width τ to the condition of 5 ns, a result was obtained in which the spectrum was completely separated into two as illustrated in the right part of FIG. 10. This is considered to be because the effect of high-frequency superimposition is reduced due to the increase in the pulse width τ. In other words, it can be said that the result of the left part of FIG. 10 is obtained by widening the spectrum of the result of the right diagram by high-frequency superimposition. Since the interval between the two separated spectra in FIG. 10 is about 3.0 nm and the two spectra are sufficiently synthesized under high-frequency superimposition, it is considered that overlapping of the spectra can be obtained when the wavelength difference Δλ of the local maximum points is 3.5 nm or less.

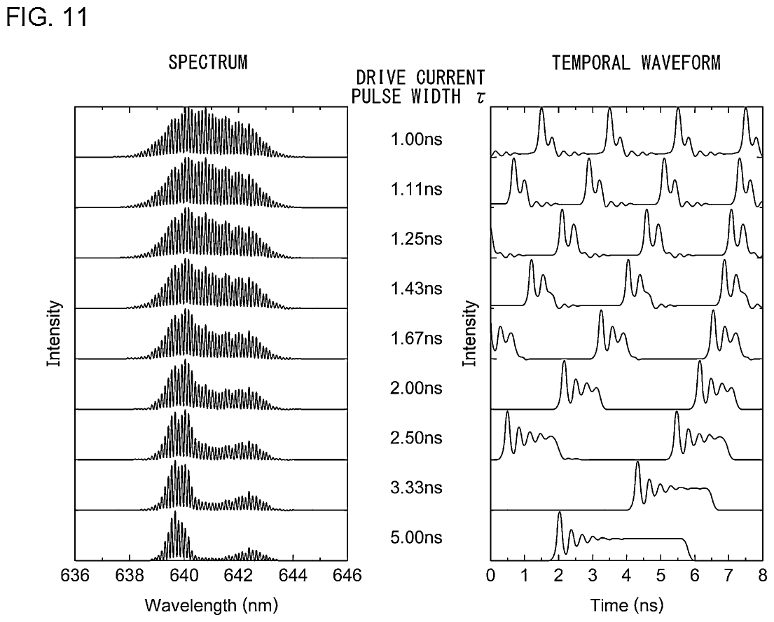

Spectra and optical waveforms were then measured under various pulse widths τ. FIG. 11 is a diagram illustrating the dependence of the spectrum and the optical waveform on a pulse width τ of a drive current I_{DRV}.

As the pulse width τ of the drive current I_{DRV} increased, the oscillation spectrum was gradually separated into two spectra. In addition, it can be seen that the two peaks are not separated at the intensity 1/e² under the condition that the pulse width of the waveform of the emitted light is 3.33 ns, but the two peaks are clearly separated under the condition that the pulse width is 5 ns. From this, it can be said that two peaks are continuous under the condition of approximately 4 ns or less.

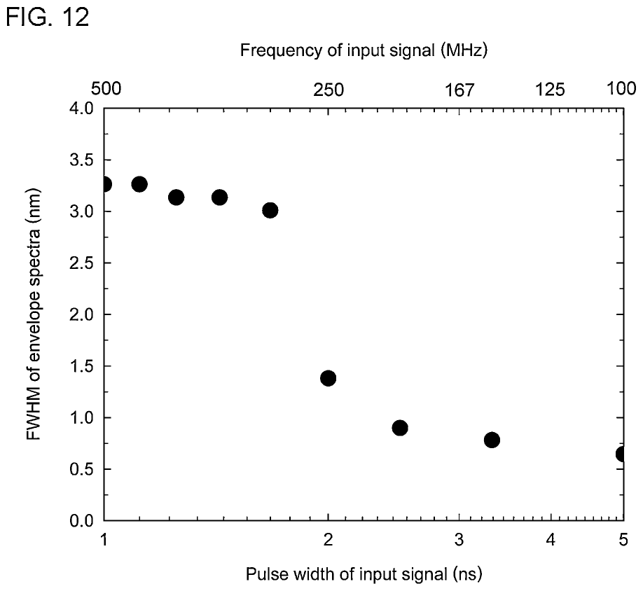

FIG. 12 is a diagram illustrating the pulse width of an optical waveform and the full width at half maximum of an envelope spectrum. It has been found that when the pulse width of the optical waveform is in the range of 2 ns or less, the full width at half maximum of the envelope exceeds 3 ns, and the effect of the technique according to the present disclosure is remarkably exhibited.

From the experimental results so far, it can be seen that a broad spectrum having a full width at half maximum exceeding 3 nm obtained under high frequency driving can be realized by synthesizing spectra oscillating at different wavelengths by the effect of high frequency superposition.

Although not illustrated here, a broad spectrum can be obtained by high-frequency pulse driving under appropriate conditions for samples created based on Example 1 and Example 3.

In summary, the technique according to the present disclosure uses (1) the semiconductor laser device 200 having a plurality of peaks in a gain spectrum and (2) the semiconductor laser device 200 capable of oscillating at multiple wavelengths in a steady state, and creates a continuous broad spectrum by operating them under an appropriate high-frequency driving condition. Using such a semiconductor laser that emits a spectrum having a large full width at half maximum as a light source for a wearable display device such as AR/VR glasses or an HMD makes it possible to improve image quality.

The semiconductor laser device of the former (1) can be realized using the asymmetric quantum well described in Example 2 or the selective growth technique described in Example 3. The latter case (2) can be realized by actively using kink described in Example 1 in addition to the asymmetric quantum well described in Example 2 and the selective growth technique described in Example 3. The state of the gain can be evaluated by the Hakki-Paoli method when it is equal to or less than a threshold value.

### MODIFICATION

It is understood by those skilled in the art that the above-described embodiments are examples, and various modifications can be made to combinations of the respective components and the respective processing processes.

Hereinafter, such modifications will be described.

### First Modification

The waveform of the drive current I_{DRV} is not limited to the waveform illustrated in FIG. 8, and any waveform may be used as long as the spectrum width can be widened.

### Second Modification

The semiconductor laser device 200 may include a plurality of emitters.

The embodiments merely illustrate the principle and application of the present disclosure, and many modifications and changes in arrangement can be made to the embodiments without departing from the spirit of the present disclosure defined in the claims.

### Supplement

The technique disclosed in the present specification can also be grasped as follows.

### Item 1

A semiconductor laser apparatus including:
an edge emitting semiconductor laser device including a light-emitting layer configured such that a plurality of peaks exist in a gain spectrum; and
a drive circuit that pulse-drives the semiconductor laser device.

### Item 2

A semiconductor laser apparatus including:
an edge emitting semiconductor laser device having non-linearity in I-L characteristics; and
a drive circuit that pulse-drives the semiconductor laser device.

### Item 3

A semiconductor laser apparatus including:
an edge emitting semiconductor laser device that oscillates with two wavelengths when CW driving is performed; and
a drive circuit that pulse-drives the semiconductor laser device.

### Item 4

The semiconductor laser apparatus according to any one of items 1 to 3, wherein an oscillation wavelength of the semiconductor laser device is in a visible light region.

### Item 5

The semiconductor laser apparatus according to any one of items 1 to 3, wherein an oscillation wavelength of the semiconductor laser device is in a red light region.

### Item 6

The semiconductor laser apparatus according to any one of items 1 to 3, wherein the spectrum of light emitted from the semiconductor laser device has a plurality of local maximum points, and the difference between a first wavelength corresponding to a largest first local maximum point and a second wavelength corresponding to a second local maximum point that is the second largest point is 1 nm or more and 10 nm or less.

### Item 7

The semiconductor laser apparatus according to item 6, wherein in an envelope of the spectrum, a local minimum point sandwiched between the first local maximum point and the second local maximum point is equal to or more than a half value of the first local maximum point.

### Item 8

The semiconductor laser apparatus according to any one of items 1 to 3, wherein a spectrum of light emitted from the semiconductor laser device has a full width at half maximum of 3 nm or more.

### Item 9

The semiconductor laser apparatus according to item 1, wherein an emission wavelength difference of 1 nm to 10 nm exists in a gain region in a chip plane of the semiconductor laser device with respect to a waveguide direction.

### Item 10

The semiconductor laser apparatus according to item 1, wherein the light-emitting layer has a stacked structure of two or more well layers having emission wavelengths different from each other by 1 nm to 10 nm.

### Item 11

The semiconductor laser apparatus according to item 1, wherein the semiconductor laser device includes a plurality of emitters.

### Item 12

The semiconductor laser apparatus according to any one of items 1 to 3, wherein the drive circuit drives the semiconductor laser device with a pulse current at which a pulse width of an optical waveform of emission light is 4 ns or less.

### Item 13

The semiconductor laser apparatus according to item 1, wherein the semiconductor laser device has a kink region in an I-L characteristic during CW driving.

### Item 14

The semiconductor laser apparatus according to item 13, wherein a peak of a pulsed drive current supplied by the drive circuit to the semiconductor laser device is located in the kink region.

### Item 15

A wearable display device including the semiconductor laser d apparatus according to any one of items 1 to 3.

What is claimed is:

1. An edge-emitting type semiconductor laser device, wherein an envelope of a spectrum of light emitted from one light emitter when laser oscillation is performed by pulse driving is formed by synthesizing spectra of a plurality of peaks, and a full width at half maximum of the envelope is 3 nm or more.

2. The semiconductor laser device according to claim 1, wherein a difference between a peak wavelength of a first spectrum which is one of the plurality of peaks located on a longest wavelength side and a peak wavelength of a second spectrum which is another of the plurality of peaks located on a shortest wavelength side peaks is 1 nm or more and 10 nm or less.

3. The semiconductor laser device according to claim 1, wherein the envelope of the spectrum of the light has a plurality of local maximum values.

4. The semiconductor laser device according to claim 3, wherein a difference between a first wavelength corresponding to a first local maximum value which is a largest local maximum value and a second wavelength corresponding to a second local maximum value which is a next largest local maximum value is 1 nm or more and 10 nm or less.

5. The semiconductor laser device according to claim 4, wherein a local minimum value sandwiched between the first local maximum value and the second local maximum value is equal to or more than a half value of the first local maximum value.

6. The semiconductor laser device according to claim 5, wherein an oscillation wavelength of the semiconductor laser device is in a visible light region.

7. The semiconductor laser device according to claim 6, wherein the oscillation wavelength of the semiconductor laser device is in a red wavelength region.

8. The semiconductor laser device according to claim 1, wherein the semiconductor laser device includes a plurality of emitters.

9. The semiconductor laser device according to claim 1, wherein an I-L characteristic during continuous wave driving has a kink region.

10. The semiconductor laser device according to claim 1, wherein an emission wavelength difference of 1 nm to 10 nm exists in a gain region in a chip plane of the semiconductor laser device with respect to a waveguide direction.

11. The semiconductor laser device according to claim 1, comprising a light-emitting layer having a stacked structure of two or more well layers having emission wavelengths different from each other by 1 nm to 10 nm.

12. The semiconductor laser device according to claim 10, comprising a light-emitting layer structured such that a plurality of peaks exist in a gain spectrum of emission light.

13. A semiconductor laser apparatus comprising:
the semiconductor laser device according to claim 1; and
a drive circuit structured to pulse-drive the semiconductor laser device.

14. The semiconductor laser apparatus according to claim 13, wherein the drive circuit drives the semiconductor laser device with a pulse current at which a pulse width of an optical waveform of emission light is 4 ns or less.

15. A semiconductor laser apparatus comprising:
the semiconductor laser device according to claim 9; and
a drive circuit structured to pulse-drive the semiconductor laser device,
wherein a peak of a pulsed drive current supplied to the semiconductor laser device is located in the kink region.

16. A wearable display device comprising the semiconductor laser apparatus according to claim 13.
